(19) United States
(12) Patent Application Publication
(10) Pub. No.: US 2019/0334021 A1
(43) Pub. Date: Oct. 31, 2019

(54) Electronic Device Including a Conductive Layer Including a Ta Si Compound and a Process of Forming the Same

(71) Applicant: Semiconductor Components Industries, LLC, Phoenix, AZ (US)

(72) Inventors: Peter Coppens, Kanegem (BE); Aurore Constant, Oudenaarde (BE)

(73) Assignee: Semiconductor Components Industries, LLC, Phoenix, AZ (US)

(21) Appl. No.: 16/510,601

(22) Filed: Jul. 12, 2019

Related U.S. Application Data
(63) Continuation-in-part of application No. 15/893,328, filed on Feb. 9, 2018.

(51) Int. Cl. H01L 29/778; H01L 29/20; H01L 29/10; H01L 29/423

(52) U.S. Cl. CPC H01L 29/7783; H01L 29/42384; H01L 29/1075; H01L 29/2003

(57) ABSTRACT

An electronic device can include a first layer including a III-V material, and a conductive layer including a first film that contacts the first layer, wherein the first film includes Ta—Si compound. In an embodiment, the electronic device can be a high electron mobility transistor (HEMT), the first layer can be a barrier layer between a channel layer and the source and drain electrodes. The source and drain electrodes are formed from the conductive layer. In a particular embodiment, the barrier layer can include AlGaN and be undoped or unintentional doped, and a Ta—Si compound can be the first film that contacts AlGaN within the barrier layer. The Ta—Si compound allows for relatively low contact resistance to be achieved without a relatively high temperature anneal or unusual sensitivity to the thickness of the first film that contains the Ta—Si compound.

### CROSS-REFERENCE TO RELATED APPLICATION

This application is a continuation-in-part of and claims priority under 35 U.S.C. § 120 to U.S. patent application Ser. No. 15/893,328 entitled “Electronic Device including a Conductive Layer Including a Ta—Si Compound and a Process of Forming the Same” by Peter Coppens and Aurore Constant, filed Feb. 9, 2018, which is assigned to the current assignee hereof and incorporated herein by reference in its entirety.

### FIELD OF THE DISCLOSURE

The present disclosure relates to electronic devices and processes of forming electronic devices, and more particularly to, electronic devices including a conductive layer that contacts another layer including a III-V material and processes of forming the same.

### RELATED ART

High electron mobility transistors can include a GaN channel layer and an overlying AlGaN barrier layer that can be undoped or unintentionally doped. Source and drain electrodes contact the barrier layer. Different metal stacks for conductive layers used in source and drain electrodes have been tried; however, one or more complications may arise including contamination concerns, relatively high temperature anneals, contact resistance being too high, or the like. Further improvement of contact resistance without other adverse complications is desired.

### BRIEF DESCRIPTION OF THE DRAWINGS

Embodiments are illustrated by way of example and are not limited in the accompanying figures.

FIG. 1 includes an illustration of a cross-sectional view of a portion of a workpiece including a substrate, a semiconductor layer, and a dielectric layer.

FIG. 2 includes an illustration of a cross-sectional view of the workpiece of FIG. 1 after patterning the dielectric layer to define contact openings.

FIG. 3 includes an illustration of a cross-sectional view of a conductive layer.

FIG. 4 includes an illustration of a cross-sectional view of the workpiece of FIG. 2 after source and drain electrodes.

FIG. 5 includes an illustration of a cross-sectional view of the workpiece of FIG. 4 after forming a gate electrode.

FIG. 6 includes an illustration of a cross-sectional view of a workpiece in which source and drain electrodes lie within recessions in a barrier layer, in accordance with another embodiment.

FIG. 7 includes plots of contact resistance for different thicknesses for films within conductive layers.

FIG. 8 includes plots of contact resistance for different compositions of the conductive layer when annealed at a range of temperatures.

FIG. 9 includes plots of contact resistance for different compositions of the conductive layer when annealed at a range of temperatures for different anneal times.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

A III-V material is intended to mean a material that includes at least one Group 13 element and at least one Group 15 element. A III-N material is intended to mean a semiconductor material that includes at least one Group 13 element and nitrogen.

The term “power transistor” is intended to mean a transistor that is designed to normally operate with at least a 50 V difference maintained between the source and drain of the transistor or emitter and collector of the transistor when the transistor is in an off-state. For example, when the transistor is in an off-state, a 50 V difference may be maintained between the source and drain without a junction breakdown or other undesired condition occurring.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about”, “approximately”, or “substantially” is intended to mean that a value of a parameter is close to a stated value or position. However, minor differences may prevent the values or positions from being exactly as stated. Thus, differences of up to ten percent (10%) (up to 20% for dopant concentrations) for the value are reasonable differences from the ideal goal of exactly as described.

Group numbers correspond to columns within the Periodic Table of Elements based on the IUPAC Periodic Table of Elements, version dated Nov. 28, 2016.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

An electronic device can include a first layer including a III-V material, and a conductive layer including a first film that contacts the first layer, wherein the first film includes Ta—Si compound. In an embodiment, the electronic device can be a high electron mobility transistor (HEMT), and the first layer can be a barrier layer between a channel layer and source and drain electrodes of the HEMT. The source and drain electrodes are formed from the conductive layer. In a particular embodiment, the barrier layer can include AlGaN and can be undoped or unintentionally doped, and the Ta—Si compound, such as TaSi₂, can be the first film that contacts AlGaN within the barrier layer. The Ta—Si compound allows for relatively low contact resistance to be achieved without a relatively high anneal temperature seen with some metallurgies of conductive layers or contact resistance that is unusually sensitive to relatively small changes in thickness when Ta, rather than a Ta—Si compound, is used. The concepts are better understood after reading the specification in conjunction with the figures.

FIG. 1 includes a cross-sectional view of a portion of a workpiece that includes a HEMT 100. The HEMT 100 can include a substrate 110, a semiconductor stack 120, and a dielectric layer 140. The substrate 110 can include silicon, sapphire (monocrystalline Al₂O₃), silicon carbide (SiC), aluminum nitride (AlN), gallium oxide (Ga₂O₃), spinel (MgAl₂O₄), another suitable substantially monocrystalline material, or the like. The particular material and crystal orientation along the primary surface can be selected depending upon the composition of the semiconductor stack 120 that will be subsequently formed over the substrate 110.

The semiconductor stack 120 can include a buffer layer 122, a channel layer 124, and a barrier layer 126. Each of the layers within the semiconductor stack 120 can include a III-N material, and in a particular embodiment include AlₓGa₍₁₋ₓ₎N, where 0≤x≤1. The composition of the buffer layer 122 may depend on the composition of the channel layer 124. The composition of the buffer layer 122 can be changed as a function of thickness, such that the buffer layer 122 has a relatively greater aluminum content closer to the substrate 110 and relatively greater gallium content closer to the channel layer 124. In a particular embodiment, the cation (metal atoms) content in the buffer layer 122 near the substrate 110 can be 10 atomic % to 100 atomic % Al with the remainder Ga, and the cation content in the buffer layer 122 near the channel layer 124 can be 0 atomic % to 50 atomic % Al with the remainder Ga. The buffer layer 122 can have a thickness in a range of approximately 1 micron to 5 microns.

The channel layer 124 can include Al_{y}Ga_{(1-y)}N, where 0≤y≤0.1 and have a thickness in a range of approximately 20 nm to 4000 nm. The barrier layer 126 can be used to help reduce the likelihood of migration of contaminants or other materials between one or more layers underlying the barrier layer 126 and the dielectric layer 140. In an embodiment, the barrier layer 126 includes a III-V material. In a particular embodiment, the barrier layer 126 can include Al_{z}Ga_{(1-z)}N, wherein 0.02≤z≤0.5, and in a further embodiment 0.11≤z≤0.3. The barrier layer 126 can have a thickness in a range of approximately 2 nm to 40 nm. In another embodiment, the barrier layer can have a thickness of at least 6 nm to ensure better that the barrier layer 126 is continuous over the channel layer 124. In another embodiment, the barrier layer 126 may have a thickness of at most 25 nm to keep on-state resistance relatively low.

Each of the channel layer 124 and the barrier layer 126 may be undoped or unintentionally doped. Unintentional doping may occur due to reactions involving the precursors during formation of the layers 124 and 126. In an embodiment, acceptors can include carbon from a source gas (e.g., Ga(CH₃)₃) when metalorganic chemical vapor deposition (MOCVD) is used to form the channel and barrier layers 124 and 126. Thus, some carbon can become incorporated as the layers 124 and 126 are grown, and such carbon can result in unintentional doping. The carbon content may be controlled by controlling the deposition conditions, such as the deposition temperature and flow rates. In an embodiment, each of the channel and barrier layers 124 and 126 has a carrier impurity concentration that is greater than 0 and less than 1×10¹⁴ atoms/cm³ or less than 1×10¹⁵ atoms/cm³ and in another embodiment, at most 1×10¹⁶ atoms/cm³. In a further embodiment, the carrier impurity concentration with unintentional doping is in a range from 1×10¹³ atoms/cm³ to 1×10¹⁶.

The semiconductor stack 120 is formed using an epitaxial growth technique, and thus the channel layer 124 and barrier layer 126, and at least a portion of the buffer layer 122 can be monocrystalline. In a particular embodiment, metal-containing films can be formed using metalorganic chemical vapor deposition. In another embodiment, different composition for the semiconductor stack 120 may be used, e.g., InAlGaN, InP, or the like.

The dielectric layer 140 can have a thickness in a range of 5 nm to 500 nm. The dielectric layer 140 can be formed using a chemical or physical vapor technique.

In an embodiment, the semiconductor stack 120, and at least one of the films of the dielectric layer 140 are formed without exposing the workpiece to air or another oxygen-containing gas. Thus, the layers and films can be formed little or no oxide at an interface between any of the layers and films. In another embodiment, the workpiece may be exposed to air between forming any one or more of the films or layers. If an interfacial oxide is not to remain in the finished device, the interfacial oxide may be reduced in a reducing ambient or etched, for example, back sputtering, to remove the interfacial oxide before forming the subsequent layer or film. In still another embodiment, an oxide film may be formed and remain. For example, after forming the dielectric layer 140, the workpiece may be exposed to air before forming the capping film.

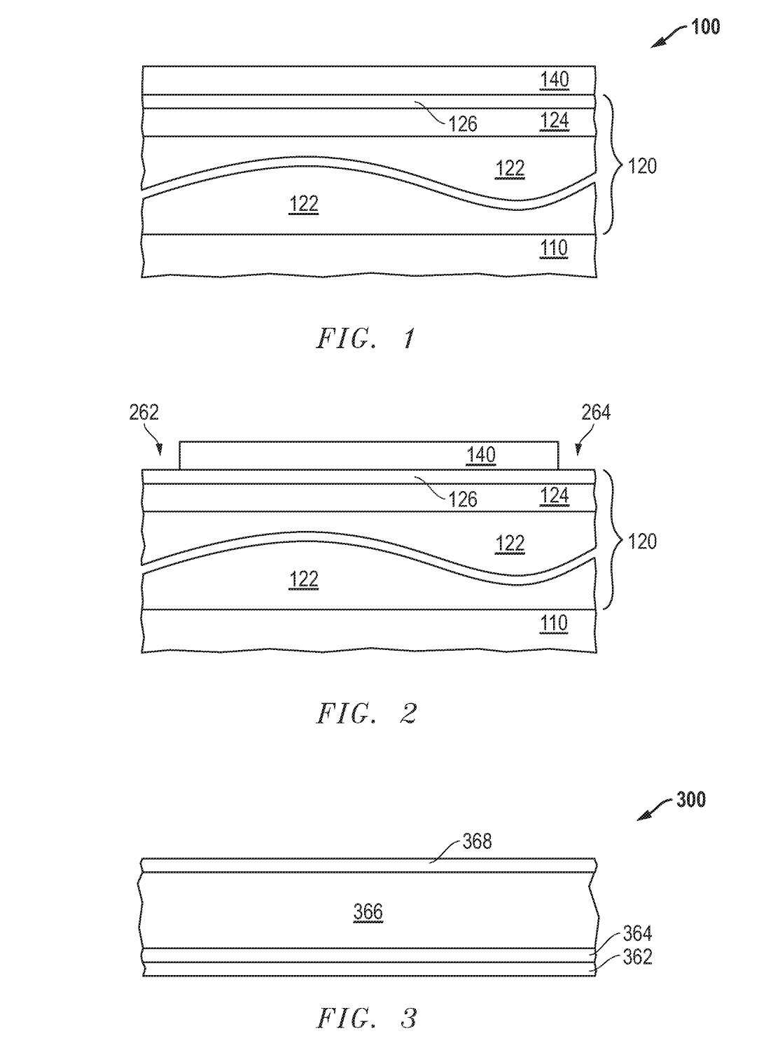

Referring to FIG. 2, the dielectric layer 140 is patterned to define contact openings 262 and 264 that expose the barrier layer 126. Some or all of the barrier layer 126 may also be removed. As illustrated in FIG. 2, none or very little of the barrier layer 126 is removed within the contact openings 262 and 264.

A conductive layer 300 is formed over the dielectric layer 140 and within the contact openings 262 and 264. The conductive layer 300 can include a plurality of films, as illustrated in FIG. 3. A lowermost film 362 contacts the barrier layer 126 and can include a Ta—Si compound. In an embodiment, the Ta—Si compound has a formula of TaSiₓ, wherein x is in a range of 1.0 to 3.0. Thus, the Ta—Si can be stoichiometric TaSi₂ or may be Ta-rich or Si-rich TaSi₂. Ta has a work function in a range of 4.0 eV to 4.8 eV, which is close to the electron affinity of GaN (approximately 4.3 eV), and Si is an electron donor with respect to III-V materials. The lowermost film 362 can have a thickness of at least 5 nm. The lowermost film should be continuous when at a thickness of 5 nm; however, a thickness of 10 nm may be used to ensure better a continuous film. Although there is not a theoretical upper limit on the thickness, as the film becomes too thick, the on-state resistance (R_{DSON}) may become unacceptable high. Thus, in an embodiment, the thickness may be at most 100 nm and, in a particular embodiment, at most 50 nm. In an embodiment, the lowermost film 362 has a thickness in a range of 5 nm to 100 nm and, in a more particular embodiment, in a range of 10 nm to 50 nm.

The conductive layer 300 can include an optional intermediate film 364. The intermediate film 364 can include a Ti-containing material, such as Ti, TiW, TiSi, TiN, or the like. The intermediate film 364 can have any of the thicknesses previously described with respect to the lowermost film 362. When present, the intermediate film 364 can have the same thickness or a different thickness as compared to lowermost film 362.

The conductive layer 300 can further include a conductive bulk film 366. The bulk film 366 can include Al, Cu, or another material that is more conductive than other films within the conductive layer 300. In an embodiment, the bulk film 366 can include at least 90 wt % Al. The bulk film 366 can have a thickness that is at least as thick as the lowermost film 362. The bulk film 366 helps to keep R_{DSON} relatively low, so the bulk film 366 is typically the thickest film within the conductive layer 300. In an embodiment, the bulk film 366 has a thickness of at least 20 nm or at least 50 nm. Although there is not a theoretical upper limit on the thickness, in an embodiment, the thickness may be at most 900 nm or at most 500 nm and, in a particular embodiment, at most 200 nm. In an embodiment, the bulk film 366 has a thickness in a range 20 nm to 900 nm and, in a more particular embodiment, in a range of 50 nm to 500 nm.

The conductive layer 300 can further include another optional film 368 overlying the bulk film 366. The film 368 can serve one or more functions. In an embodiment, the film 368 can be an anti-diffusion film, an antireflective film, or the like. The film 368 has a different composition as compare to the bulk film 366. In an embodiment, the film 368 can include TiN, W, TiW, Pd, or the like. The thickness of the film 368 may depend on the material and purpose it serves. The film 368 can have any of the thicknesses previously described with respect to the lowermost film 362. When present, the film 368 can have the same thickness or a different thickness as compared to lowermost film 362.

More or fewer films can be used in the conductive layer 300 as illustrated in FIG. 3. The number and composition of the films within the conductive layer 300 can depend on the needs or desires for a particular application. After reading this specification, skilled artisans will be able to determine the composition of the conductive layer 300 that is tailored to their devices.

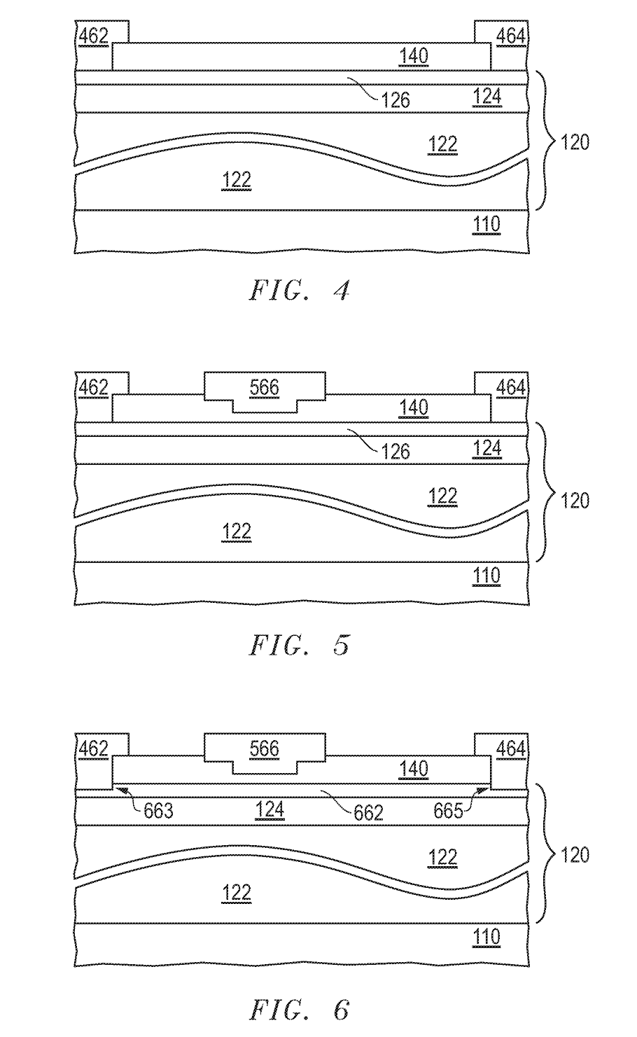

The films making up the conductive layer 300 can be serially deposited without exposure to air, without breaking vacuum, or both. In an embodiment, the films of the conductive layer 300 can be sputter deposited. The conductive layer 300 is patterned to form the source electrode 462 and the drain electrode 464, as illustrated in FIG. 4.

Another opening can be formed in the dielectric layer 140, and a gate electrode 566 can be formed in within the opening as illustrated in FIG. 5. The gate electrode 566 includes a conductive layer. The composition of the conductive layer for the gate electrode 566 may depend on whether a depletion-mode or enhancement-mode HEMT is being formed. The conductive layer for the gate electrode 566 can have the same or different composition as compared to the conductive layer for the source and drain electrodes 462 and 464. The number and composition of the films within the conductive layer for the gate electrode 566 can depend on the needs or desires for a particular application. After reading this specification, skilled artisans will be able to determine the composition of the conductive layer that is tailored to their devices. The conductive layer for the gate electrode 566 can be in a range of 110 nm to 900 nm. In another embodiment, the conductive layer may be thinner or thicker than described in the preceding range.

After forming the source and drain electrodes 462 and 464 or after forming the source, drain, and gate electrodes 462, 464, and 566, the workpiece can be annealed to form ohmic contacts between the barrier layer 126 and the source and drain electrodes 462 and 464. The anneal can be performed at a temperature in a range of 500° C. to 900° C. For a plurality of contacts, the median contact resistance may be its lowest when the anneal temperature is in a range of 650° C. to 800° C. Below 650° C., the median contact resistance may begin to significantly increase, and above 800° C., the median contact resistance may gradually increase. A lower anneal temperature is less likely to cause adverse effects to the device as compared to a higher anneal temperature. The anneal time can be in a range of 30 s to 300 s. In general, the median contact resistance decreases significantly for an anneal time of 30 s to 60 s and gradually decreases from 60 s to 120 s. After 120 s, the median contact resistance decreases slight and then become stable from 180 s to 300 s. In a particular embodiment, the anneal time is in a range of 120 s to 220 s. The anneal can be performed in a relatively inert gas, such as N₂, Ar, He, or the like. An oxidizing gas, such as O₂, N₂O, H₂O, or the like may be avoided. The anneal may not be significantly affected by pressure. In an embodiment, the anneal may be performed at approximately atmospheric pressure.

After the anneal, the median contact resistance for the source electrode 462, the drain electrode 464, or the source and drain electrodes 462 and 464 may be at most 0.40. An anneal temperature is in a range of 620° C. to 890° C., and an anneal time is approximately 30 s are particularly well suited for achieving low median contact resistance. As the anneal time is increased to 60 s, the median contact resistance can be at most 0.30 ohm·mm. A median contact resistance of at most 0.25 ohm·mm can be achieved with an anneal temperature in a range of 650° C. to 750° C. with an anneal time in a range of 90 s to 150 s. A median contact resistance of 0.20 ohm·mm can be achieved as processing parameters are optimized. Thus, good median contact resistance can be achieved at a relatively low temperature as compared to other metal stacks used in conventional conductive layers.

One or more interconnect levels and a passivation layer may be formed over the workpiece. Each interconnect level can include an interlevel dielectric layer and interconnects. A conductive layer can be used at each interconnect level. The conductive layer may be the same or different from the other conductive layers described earlier in this specification. After forming the interconnect levels and the passivation layer, an anneal may be performed. Performance of the previously described anneal may be deferred until this time, or an anneal separate from the anneal previously described may be performed. If a separate anneal is performed, it may be performed using the same or different parameters as the anneal previously described. A substantially completed electronic device has been formed.

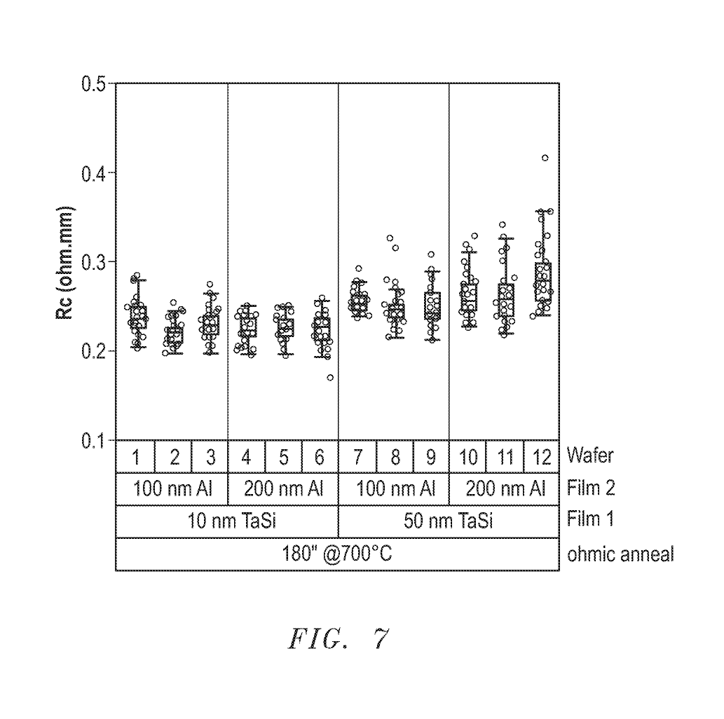

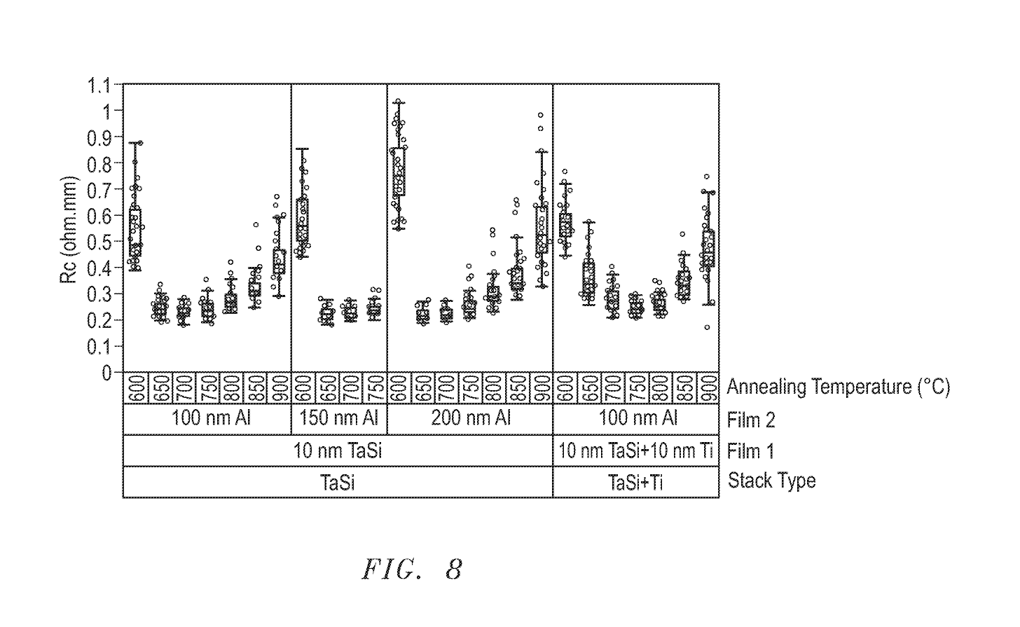

In another embodiment, the source electrode 462, the drain electrode 464, or the source and drain electrodes 462 and 464 may be recessed within a barrier layer 662, as illustrated in FIG. 6. The barrier layer 662 can have any of the compositions as previously described with respect to the barrier layer 126. In this embodiment, the barrier layer 662 may be relatively thicker than the barrier layer 126 due to concerns with interactions between layers above and below the barrier layer 662. The barrier layer 662 can be patterned to define recessions 663 and 665. The thickness of the barrier layer 662 below the recessions 663 and 665 can be any of the thicknesses as previously described with respect to the barrier layer 126. Thus, a relatively thicker barrier layer 662 can be used and still allow the proper formation of a two-dimensional electron gas for the proper operation of the HEMT.

Embodiments as described herein can help to achieve a relatively low median contact resistance without other adverse complications. The relatively low median contact resistance helps to reduce R_{DSON} for the HEMT. The significance of the low contact resistance becomes more significant as the size of contacts decreases. For example, a HEMT designed for 650 V can have a contact resistance that makes up approximately 5% of the R_{DSON}. Another HEMT designed for 200 V can have a contact resistance that makes up approximately 20% of the R_{DSON}. The 650 V device has larger contact openings as compared to the 200 V device. Thus, the improvement in contact resistance helps both devices and will be more significant in keeping R_{DSON} for the 200 V device.

The metal stack for the conductive layer previously described does not have or cause adverse complications as compared to other metal stack. A conductive layer having a metal stack of Ta/Si/Ti/Al/Ni/Ta or Ta/Ti/Al can require an anneal temperature of at least 800° C. to achieve low contact resistances as the previously described embodiments. A high anneal temperature may result in increased leakage in the GaN channel film or the buffer layer. The high anneal temperature can also significantly increase the roughness of the ohmic metal.

Another conductive layer can have a metal stack of Ta/Al/Ta or Ta/Al is believed to have a contact resistance that is sensitive to thickness of the Ta film. For example, when the Ta film contacting a barrier layer increases from 10 nm to 20 nm, the contact resistance increases by approximately 500%. When such Ta film is decreased from 10 nm to 5 nm, the contact resistance increases by approximately 50%. Therefore, such a conductive layer is not well suited for a manufacturing process.

The metal stack of the conductive layer previously described with respect to the source and drain electrodes 462 and 464 is well suited to provide good median contact resistance, as the lowermost film 362 of the conductive layer 300 is not as sensitive to thickness variation as compared to the Ta/Al/Ta or Ta/Al conductive layer and can be annealed at a significantly lower temperature as compared to the Ta/Si/Ti/Al/Ni/Ta or Ta/Ti/Al conductive layer. Furthermore, the conductive layers as described herein do not include Au, and thus, contamination issues seen with Au are obviated.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

Embodiment 1. An electronic device can include a first layer including Al_{z}Ga_{(1-z)}N, wherein 0.02≤z≤0.5, wherein the first layer is undoped or has a dopant concentration at most 1×10¹⁶ atoms/cm³; and a conductive layer including a first film that contacts the first layer at a plurality of locations, wherein the first film includes a Ta—Si compound, and the first and conductive layers have a corresponding median contact resistance of at most 0.40 ohm·mm.

Embodiment 2. The electronic device of Embodiment 1, wherein the first and conductive layers has a corresponding median contact resistance of at most 0.35 ohm·mm.

Embodiment 3. The electronic device of Embodiment 1, wherein the first and conductive layers has a corresponding median contact resistance of at most 0.30 ohm·mm.

Embodiment 4. The electronic device of Embodiment 1, wherein the first and conductive layers has a corresponding median contact resistance is at least 0.20 ohm·mm.

Embodiment 5. The electronic device of Embodiment 1, wherein the Ta—Si compound has a formula of TaSiₓ, wherein xis in a range of 1.5 to 3.0.

Embodiment 6. The electronic device of Embodiment 1, wherein the first film has a thickness of at least 6 nm.

Embodiment 7. The electronic device of Embodiment 6, wherein the first film has a thickness of at most 40 nm.

Embodiment 8. The electronic device of Embodiment 1, wherein the conductive layer further includes a second film that includes at least 90 wt % Al.

Embodiment 9. The electronic device of Embodiment 8, wherein the conductive layer further includes a third film, wherein the second film is disposed between the first and third films, and the third film has a composition different from each of the second film.

Embodiment 10. The electronic device of Embodiment 1, wherein the first layer includes Al_{z}Ga_{(1-z)}N, where 0.11≤z≤0.3.

Embodiment 11. The electronic device of Embodiment 1, including a high electron mobility transistor that includes the first layer.

Embodiment 12. The electronic device of Embodiment 11, wherein the high electron mobility transistor includes a channel layer that includes a III-V compound, wherein the first layer is disposed between the channel layer and the conductive layer.

Embodiment 13. The electronic device of Embodiment 12, wherein the channel layer is a GaN layer.

Embodiment 14. The electronic device of Embodiment 12, a source electrode of the high electron mobility transistor, a drain electrode of the high electron mobility transistor, or both the source and drain electrodes include the conductive layer.

Embodiment 15. The electronic device of Embodiment 14, wherein the high electron mobility transistor further includes a gate electrode having a different composition as compared to the source and drain electrodes.

Embodiment 16. An electronic device can including a high-electron mobility transistor including a channel layer including GaN; a barrier layer overlying the channel layer and including AlₓGa₍₁₋ₓ₎N, where 0.11≤x≤0.3; a source electrode contacting the barrier layer; and a drain electrode spaced apart from the source electrode and contacting the barrier layer. The source electrode, the drain electrode, or both the source and drain electrodes can include a conductive layer that includes a first film contacting the barrier layer and including a Ta—Si compound, and a second film that includes at least 90 wt % Al, and a median contact resistance for the barrier layer and either or both of the source and drain electrodes is at most 0.40 ohm·mm.

Embodiment 17. The electronic device of Embodiment 16, wherein a median contact resistance for the barrier layer and either or both of the source and drain electrodes is at most 0.30 ohm·mm.

Embodiment 18. A process of forming an electronic device can include providing a first layer over a substrate, wherein the first layer includes Al_{z}Ga_{(1-z)}N, wherein 0.02≤z≤0.5 and is undoped or has a dopant concentration at most 1×10¹⁶ atoms/cm³; and forming a conductive layer including a first film that contacts the first layer at a plurality of locations, wherein the first film includes a Ta—Si compound, and the first and conductive layers have a corresponding median contact resistance of at most 0.40 ohm·mm.

Embodiment 19. The process of Embodiment 18, wherein forming the conductive layer further includes forming the first film, wherein the Ta—Si compound has a formula of TaSiₓ, wherein x is in a range of 1.0 to 3.0; forming a second film over the first film, wherein the second film includes at least 90 wt % Al; and forming a third film over the second film.

Embodiment 20. The process of Embodiment 18, further includes annealing the first and conductive layers at a temperature in a range of 620° C. to 890° C. for a time in a range of 60 s to 300 s, wherein the median contact resistance for the first and conductive layers is at most 0.30 ohm·mm.

Embodiment 21. An electronic device can include a first layer including a III-V material; and a conductive layer including a first film that contacts the first layer, wherein the first film includes Ta—Si compound.

Embodiment 22. The electronic device of Embodiment 21, wherein the Ta—Si compound has a formula of TaSiₓ, wherein x is in a range of 1.0 to 3.0.

Embodiment 23. The electronic device of Embodiment 21, wherein the first film has a thickness in a range of 5 nm to 100 nm.

Embodiment 24. The electronic device of Embodiment 21, wherein the first and conductive layers has a corresponding contact resistance of at most 1 ohm·mm.

Embodiment 25. The electronic device of Embodiment 21, wherein the conductive layer further includes a second film that includes at least 90 wt % Al.

Embodiment 26. The electronic device of Embodiment 25, further including a Ti-containing film between the first film and the second film.

Embodiment 27. The electronic device of Embodiment 25, wherein the conductive layer further includes a third film, wherein the second film is disposed between the first and third films.

Embodiment 28. The electronic device of Embodiment 27, wherein the third film has a composition different from each of the second film.

Embodiment 29. The electronic device of Embodiment 27, wherein the third film includes TiN, W, TiW, or Pd.

Embodiment 30. The electronic device of Embodiment 21, wherein the first layer includes Al_{z}Ga_{(1-z)}N, where 0.02≤z≤0.5.

Embodiment 31. The electronic device of Embodiment 21, including a high electron mobility transistor that includes the first layer.

Embodiment 32. The electronic device of Embodiment 31, wherein the high electron mobility transistor includes a channel layer that includes a III-V compound, wherein the first layer is disposed between the channel layer and the conductive layer.

Embodiment 33. The electronic device of Embodiment 32, wherein the channel layer is a GaN layer.

Embodiment 34. The electronic device of Embodiment 32, a source electrode of the high electron mobility transistor, a drain electrode of the high electron mobility transistor, or both the source and drain electrodes include the conductive layer.

Embodiment 35. The electronic device of Embodiment 34, wherein the high electron mobility transistor further includes a gate electrode having a different composition as compared to the source and drain electrodes.

Embodiment 36. An electronic device can include a high-electron mobility transistor, the high-electron mobility transistor including: a channel layer including GaN; a barrier layer overlying the channel layer and including Al,Ga₍₁₋ₓ₎N, where 0.05≤x≤0.3; a source electrode contacting the barrier layer; and a drain electrode spaced apart from the source electrode and contacting the barrier layer, wherein the source electrode, the drain electrode, or both the source and drain electrodes include a conductive layer that includes a first film contacting the barrier layer and including TaSi₂, a second film that includes at least 90 wt % Al, and a third layer that is relatively inert with respect to Al.

Embodiment 37. The electronic device of Embodiment 36, wherein a contact resistance for the barrier layer and either or both of the source and drain electrodes is at most 0.30 ohm·mm.

Embodiment 38. A process of forming an electronic device including providing a first layer including a III-V material over a substrate; and forming a conductive layer contacting the first layer, wherein the conductive layer includes a first film that includes Ta—Si compound.

Embodiment 39. The process of Embodiment 38, wherein forming the conductive layer further includes forming the first film; forming a second film over the first film, wherein the second film includes at least 90 wt % Al; and forming a third film over the second film.

Embodiment 40. The process of Embodiment 38, further including annealing the first and conductive layers at a temperature in a range of 500° C. to 900° C., wherein a contact resistance for the first and conductive layers is at most 0.30 ohm·mm.

### EXAMPLES

The follow examples are provided to demonstrate that a conductive layer having a lowermost film including a Ta—Si compound can achieve good median contact resistance for different compositions of overlying films within the conductive layer and when processing parameters are varied. The conductive layer contacted an underlying layer having a composition of Al_{0.25}Ga_{0.75}N that is unintentionally doped (dopant concentration at most 1×10¹⁶ atoms/cm³). The TaSi films referred to below were deposited using a nominal TaSi₂ target having a Si/Ta ratio of 2.5+/−0.1. The Al films referred to below included Al with 0.5 wt % Cu.

Box plots are used in conjunction with the date presented in many of the figures reference below. Note the following aspects about outlier box plots:
The horizontal line within the box represents the median sample value.
The ends of the box represent the 25th and 75th quantiles, also expressed as the 1st and 3rd quartile, respectively.
The difference between the 1st and 3rd quartiles is called the interquartile range.
The box has lines that extend from each end, sometimes called whiskers. The whiskers extend from the ends of the box to the outermost data point that falls within the distances computed as follows:
   1st quartile−1.5*(interquartile range)
   3rd quartile+1.5*(interquartile range)
If the data points do not reach the computed ranges, then the whiskers are determined by the upper and lower data point values (not including outliers).

FIG. 7 includes plots of contact resistance for conductive layers having different thicknesses of a TaSi film and an Al film overlying the TaSi film. In particular, the thicknesses tested were approximately 10 nm and approximately 50 nm for the TaSi film and approximately 100 nm and approximately 200 nm for the Al film. The samples were annealed for 180 s at approximately 700° C. At a thickness of 10 nm for the TaSi film, the median contact resistance was approximately 0.225 ohm·mm for both thicknesses of the Al film. The median contact resistance was slightly higher for the thicker TaSi film. The median contact resistance for approximately 50 nm TaSi/approximately 100 nm Al was approximately 0.25 ohm·mm, and the median contact resistance for approximately 50 nm TaSi/approximately 200 Al was approximately 0.26 ohm·mm.

Tables 1 and 2 below includes the median contact resistance and standard deviation for the samples referenced in FIG. 7.

TABLE 1
10 nm TaSi Samples in FIG. 7

| | Wafer ID | | | | | |
|---|---|---|---|---|---|---|
| | 1 | 2 | 3 | 4 | 5 | 6 |
| 75^{th} Percentile Contact | 0.248 | 0.224 | 0.239 | 0.235 | 0.233 | 0.236 |
| Resistance (ohm · mm) | | | | | | |
| Median Contact | 0.235 | 0.220 | 0.228 | 0.221 | 0.224 | 0.225 |
| Resistance (ohm · mm) | | | | | | |
| 25^{th} Percentile Contact | 0.226 | 0.208 | 0.218 | 0.216 | 0.215 | 0.210 |
| Resistance (ohm · mm) | | | | | | |

TABLE 2
50 nm TaSi Samples in FIG. 7

| | Wafer ID | | | | | |
|---|---|---|---|---|---|---|
| | 7 | 8 | 9 | 10 | 11 | 12 |
| 75^{th} Percentile Contact | 0.260 | 0.249 | 0.262 | 0.272 | 0.271 | 0.296 |
| Resistance (ohm · mm) | | | | | | |
| Median Contact | 0.252 | 0.244 | 0.240 | 0.253 | 0.255 | 0.276 |
| Resistance (ohm · mm) | | | | | | |
| 25^{th} Percentile Contact | 0.243 | 0.234 | 0.233 | 0.243 | 0.236 | 0.253 |
| Resistance (ohm · mm) | | | | | | |

FIG. 8 includes plots of contact resistance using different compositions of the conductive layer at different annealing temperatures. The anneal time for the samples in FIG. 8 was 180 s. The compositions of the conductive layer included an approximately 10 nm TaSi film and different thicknesses of Al films, namely, approximately 100 nm Al, approximately 150 nm Al, and approximately 200 nm Al. One sample included a lowermost film of approximately 10 nm TaSi, an intermediate film of approximately 10 nm Ti, and an uppermost film of approximately 100 nm Al.

The conductive layers with TaSi/Al are similar and have significant reduction in median contact resistance between 600° C. and 650° C. with median contact resistance reaching 0.40 ohm·mm at approximately 620° C. The lowest median contact resistance is approximately 0.22 ohm·mm at an anneal temperature in a range of 650° C. to 750° C. For anneal temperatures above 750° C., the median contact resistance gradually increases, such that the median contact resistance reaches 0.40 ohm·mm at approximately 870° C.

The conductive layer with TaSi/Ti/Al has a more gradual decrease in median contact resistance between 600° C. and 650° C. with median contact resistance reaching 0.40 ohm·mm at approximately 620° C. The lowest median contact resistance is approximately 0.23 ohm·mm at an anneal temperature in a range of 700° C. to 800° C. For anneal temperatures above 800° C., the median contact resistance gradually increases, such that the median contact resistance reaches 0.40 ohm·mm at approximately 890° C.

Tables 3 to 6 below includes the median contact resistance and standard deviation for the samples referenced in FIG. 8.

TABLE 3
10 nm TaSi/100 nm Al Sample in FIG. 8

| | Anneal Temperature (° C.) | | | | | | |
|---|---|---|---|---|---|---|---|
| | 600 | 650 | 700 | 750 | 800 | 850 | 900 |
| 75^{th} Percentile Contact | 0.620 | 0.261 | 0.243 | 0.263 | 0.296 | 0.344 | 0.467 |
| Resistance | | | | | | | |
| (ohm · mm) | | | | | | | |
| Median Contact | 0.485 | 0.242 | 0.225 | 0.239 | 0.267 | 0.313 | 0.408 |
| Resistance | | | | | | | |
| (ohm · mm) | | | | | | | |
| 25^{th} Percentile Contact | 0.449 | 0.224 | 0.218 | 0.215 | 0.249 | 0.295 | 0.380 |
| Resistance | | | | | | | |
| (ohm · mm) | | | | | | | |

TABLE 4
10 nm TaSi/150 nm Al Sample in FIG. 8

Anneal Temperature (° C.)

| | 600 | 650 | 700 | 750 |
|---|---|---|---|---|
| 75^{th} Percentile Contact | 0.662 | 0.241 | 0.246 | 0.252 |
| Resistance (ohm · mm) | | | | |
| Median Contact | 0.557 | 0.223 | 0.223 | 0.238 |
| Resistance (ohm · mm) | | | | |
| 25^{th} Percentile Contact | 0.504 | 0.205 | 0.212 | 0.228 |
| Resistance (ohm · mm) | | | | |

TABLE 5
10 nm TaSi/200 nm Al Sample in FIG. 8

| | Anneal Temperature (° C.) | | | | | | |
|---|---|---|---|---|---|---|---|
| | 600 | 650 | 700 | 750 | 800 | 850 | 900 |
| 75^{th} Percentile Contact | 0.856 | 0.237 | 0.237 | 0.276 | 0.329 | 0.400 | 0.638 |
| Resistance | | | | | | | |
| (ohm · mm) | | | | | | | |
| Median Contact | 0.753 | 0.219 | 0.218 | 0.249 | 0.295 | 0.348 | 0.528 |
| Resistance | | | | | | | |
| (ohm · mm) | | | | | | | |
| 25^{th} Percentile Contact | 0.678 | 0.208 | 0.208 | 0.235 | 0.275 | 0.319 | 0.459 |
| Resistance | | | | | | | |
| (ohm · mm) | | | | | | | |

TABLE 6
10 nm TaSi/10 nm Ti/100 nm Al Sample in FIG. 8

| | Anneal Temperature (° C.) | | | | | | |
|---|---|---|---|---|---|---|---|
| | 600 | 650 | 700 | 750 | 800 | 850 | 900 |
| 75^{th} Percentile Contact | 0.611 | 0.424 | 0.307 | 0.269 | 0.280 | 0.390 | 0.543 |
| Resistance | | | | | | | |
| (ohm · mm) | | | | | | | |
| Median Contact | 0.576 | 0.340 | 0.274 | 0.244 | 0.252 | 0.333 | 0.459 |
| Resistance | | | | | | | |
| (ohm · mm) | | | | | | | |
| 25^{th} Percentile Contact | 0.524 | 0.307 | 0.249 | 0.230 | 0.240 | 0.304 | 0.413 |
| Resistance | | | | | | | |
| (ohm · mm) | | | | | | | |

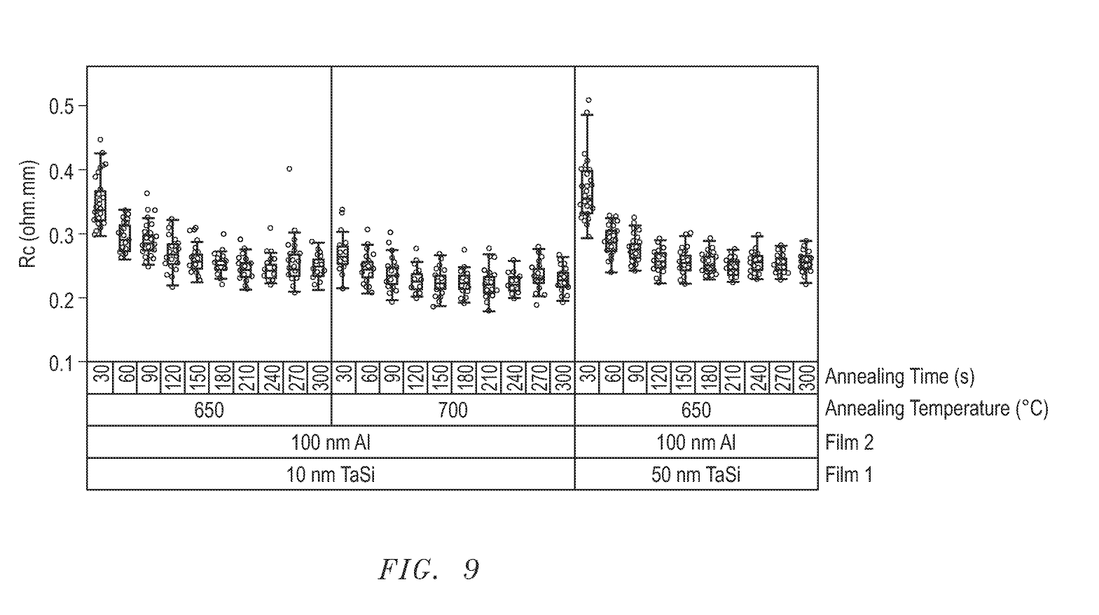

FIG. 9 includes plots of contact resistance for difference annealing times. The samples had conductive layers that included approximately 10 nm and approximately 50 nm TaSi films and an overlying approximately 100 nm Al film. Annealing times were at approximately 650° C. and approximately 700° C. All samples showed a significant decrease in median contact resistance between 30 s to 60 s and a more gradual decrease in median contact resistance between 60 s to 180 s. Median contact resistance did not significantly decrease with anneal times over 180 s. All data for the three samples had median contact resistances less than 0.40 ohm·mm.

Tables 7 to 12 below includes the median contact resistance and standard deviation for the samples referenced in FIG. 8.

TABLE 7
10 nm TaSi/100 nm Al Sample Annealed at 650° C. in FIG. 9

| | Anneal Time (s) | | | | |
|---|---|---|---|---|---|
| | 30 | 60 | 90 | 120 | 150 |
| 75^{th} Percentile Contact | 0.370 | 0.317 | 0.303 | 0.289 | 0.273 |
| Resistance (ohm · mm) | | | | | |
| Median Contact | 0.342 | 0.296 | 0.290 | 0.273 | 0.263 |
| Resistance (ohm · mm) | | | | | |
| 25^{th} Percentile Contact | 0.327 | 0.278 | 0.279 | 0.260 | 0.251 |
| Resistance (ohm · mm) | | | | | |

TABLE 8
10 nm TaSi/100 nm Al Sample Annealed at 650° C. in FIG. 9

| | Anneal Time (s) | | | | |
|---|---|---|---|---|---|
| | 180 | 210 | 240 | 270 | 300 |
| 75^{th} Percentile Contact | 0.263 | 0.261 | 0.258 | 0.273 | 0.266 |
| Resistance (ohm · mm) | | | | | |
| Median Contact | 0.257 | 0.249 | 0.249 | 0.251 | 0.256 |
| Resistance (ohm · mm) | | | | | |
| 25^{th} Percentile Contact | 0.251 | 0.240 | 0.238 | 0.240 | 0.241 |
| Resistance (ohm · mm) | | | | | |

TABLE 9
10 nm TaSi/100 nm Al Sample Annealed at 700° C. in FIG. 9

| | Anneal Time (s) | | | | |
|---|---|---|---|---|---|
| | 30 | 60 | 90 | 120 | 150 |
| 75^{th} Percentile Contact | 0.286 | 0.261 | 0.252 | 0.243 | 0.242 |
| Resistance (ohm · mm) | | | | | |
| Median Contact | 0.271 | 0.249 | 0.240 | 0.231 | 0.228 |
| Resistance (ohm · mm) | | | | | |
| 25^{th} Percentile Contact | 0.259 | 0.239 | 0.230 | 0.223 | 0.219 |
| Resistance (ohm · mm) | | | | | |

TABLE 10
10 nm TaSi/100 nm Al Sample Annealed at 700° C. in FIG. 9

| | Anneal Time (s) | | | | |
|---|---|---|---|---|---|
| | 180 | 210 | 240 | 270 | 300 |
| 75^{th} Percentile Contact | 0.239 | 0.240 | 0.238 | 0.251 | 0.244 |
| Resistance (ohm · mm) | | | | | |
| Median Contact | 0.229 | 0.225 | 0.227 | 0.234 | 0.233 |
| Resistance (ohm · mm) | | | | | |
| 25^{th} Percentile Contact | 0.220 | 0.215 | 0.217 | 0.229 | 0.224 |
| Resistance (ohm · mm) | | | | | |

TABLE 11
50 nm TaSi/100 nm Al Sample Annealed at 650° C. in FIG. 9

| | Anneal Time (s) | | | | |
|---|---|---|---|---|---|
| | 30 | 60 | 90 | 120 | 150 |
| 75^{th} Percentile Contact | 0.400 | 0.310 | 0.290 | 0.274 | 0.271 |
| Resistance (ohm · mm) | | | | | |
| Median Contact | 0.359 | 0.292 | 0.282 | 0.264 | 0.259 |
| Resistance (ohm · mm) | | | | | |
| 25^{th} Percentile Contact | 0.335 | 0.278 | 0.270 | 0.253 | 0.250 |
| Resistance (ohm · mm) | | | | | |

TABLE 12
50 nm TaSi/100 nm Al Sample Annealed at 650° C. in FIG. 9

| | Anneal Time (s) | | | | |
|---|---|---|---|---|---|
| | 180 | 210 | 240 | 270 | 300 |
| 75^{th} Percentile Contact | 0.268 | 0.261 | 0.271 | 0.266 | 0.270 |
| Resistance (ohm · mm) | | | | | |
| Median Contact | 0.256 | 0.250 | 0.261 | 0.258 | 0.262 |
| Resistance (ohm · mm) | | | | | |
| 25^{th} Percentile Contact | 0.249 | 0.243 | 0.249 | 0.250 | 0.252 |
| Resistance (ohm · mm) | | | | | |

The data above can be compared to US 2015/0364330 (“Chen”) Chen discloses metal layers for use in metal contacts. Chen disclosed a first stack with 20 nm Ta/20 nm Ta/50 nm Ti/50 nm Al as illustrated in FIG. 8A, and a second stack with 40 nm Ta/50 nm Ti/50 nm Al as illustrated in FIG. 8B. With respect to the first stack, after evaporation the lower 20 nm Ta layers, the substrate and the lower 20 nm Ta are cooled to 30° C. before evaporating the upper 20 nm Ta layer. The stacks included one or more Ta layers. Ta is not a Ta—Si compound.

FIG. 10B of Chen includes plots a parameter Rt (in units of ohm.mm) that corresponds to contact resistance as used in this specification for different wafers from different lots. Lot HV07L22 had a 4 nm AlGaN layer, and lot HV07L24 had a 5 nm AlGaN layer. Wafer GA591C was rapid thermal annealed at 800° C. for 30 s, wafer GA602A was rapid thermal annealed at 800° C. for 15 s, and wafer GA602B was rapid thermal annealed at 800° C. for 30 s. The best median contact resistance was 0.47 ohm·mm for wafer GA591C. Wafer GA602A had a median contact resistance of 0.75 ohm·mm, and wafer GA602B had a contact resistance of 0.67 ohm·mm.

Unexpectedly, the median contact resistance is significantly lower when a Ta—Si compound is used as compared to using Ta. A median contact resistance of at most 0.40 ohm·mm is a 15% reduction in median contact resistance as compared to GA591C, which is the best reported sample in Chen. Many samples in this application have a median contact resistance of at most 0.35 ohm·mm, which is a 26% reduction in median contact resistance as compared to the best reported sample in Chen. Furthermore, a substantial fraction of samples in this application have a median contact resistance of at most 0.30 ohm·mm, which is a 36% reduction in median contact resistance as compared to the best reported sample in Chen. The metallurgy for the conductive layers as described in this application are a significant improvement over Chen. Skilled artisans would not have reasonably expected that the median contact resistance would be significantly reduced compared to the Ta metallurgy disclosed in Chen.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. An electronic device comprising:
a first layer including Al_{z}Ga_{(1-z)}N, wherein 0.02≤z≤0.5, wherein the first layer is undoped or has a dopant concentration at most 1×10¹⁶ atoms/cm³; and
a conductive layer including a first film that contacts the first layer at a plurality of locations, wherein the first film includes a Ta—Si compound, and the first and conductive layers have a corresponding median contact resistance of at most 0.40 ohm·mm.

2. The electronic device of claim 1, wherein the first and conductive layers has a corresponding median contact resistance of at most 0.35 ohm·mm.

3. The electronic device of claim 1, wherein the first and conductive layers has a corresponding median contact resistance of at most 0.30 ohm·mm.

4. The electronic device of claim 1, wherein the first and conductive layers has a corresponding median contact resistance is at least 0.20 ohm·mm.

5. The electronic device of claim 1, wherein the Ta—Si compound has a formula of TaSiₓ, wherein x is in a range of 1.5 to 3.0.

6. The electronic device of claim 1, wherein the first film has a thickness of at least 6 nm.

7. The electronic device of claim 6, wherein the first film has a thickness of at most 40 nm.

8. The electronic device of claim 1, wherein the conductive layer further comprises a second film that includes at least 90 wt % Al.

9. The electronic device of claim 8, wherein the conductive layer further comprises a third film, wherein the second film is disposed between the first and third films, and the third film has a composition different from each of the second film.

10. The electronic device of claim 1, wherein the first layer includes Al_{z}Ga_{(1-z)}N, where 0.11≤z≤0.3.

11. The electronic device of claim 1, comprising a high electron mobility transistor that includes the first layer.

12. The electronic device of claim 11, wherein the high electron mobility transistor comprises a channel layer that includes a III-V compound, wherein the first layer is disposed between the channel layer and the conductive layer.

13. The electronic device of claim 12, wherein the channel layer is a GaN layer.

14. The electronic device of claim 12, a source electrode of the high electron mobility transistor, a drain electrode of the high electron mobility transistor, or both the source and drain electrodes include the conductive layer.

15. The electronic device of claim 14, wherein the high electron mobility transistor further comprises a gate electrode having a different composition as compared to the source and drain electrodes.

16. An electronic device comprising:
a high-electron mobility transistor including:
a channel layer including GaN;
a barrier layer overlying the channel layer and including AlₓGa₍₁₋ₓ₎N, where 0.11≤x≤0.3;
a source electrode contacting the barrier layer; and
a drain electrode spaced apart from the source electrode and contacting the barrier layer,
wherein the source electrode, the drain electrode, or both the source and drain electrodes include a conductive layer that includes a first film contacting the barrier layer and including a Ta—Si compound, and a second film that includes at least 90 wt % Al, and a median contact resistance for the barrier layer and either or both of the source and drain electrodes is at most 0.40 ohm·mm.

17. The electronic device of claim 16, wherein a median contact resistance for the barrier layer and either or both of the source and drain electrodes is at most 0.30 ohm·mm.

18. A process of forming an electronic device comprising:
providing a first layer over a substrate, wherein the first layer includes Al_{z}Ga_{(1-z)}N, wherein 0.02≤z≤0.5 and is undoped or has a dopant concentration at most 1×10¹⁶ atoms/cm³; and
forming a conductive layer including a first film that contacts the first layer at a plurality of locations, wherein the first film includes a Ta—Si compound, and the first and conductive layers have a corresponding median contact resistance of at most 0.40 ohm·mm.

19. The process of claim 18, wherein forming the conductive layer further comprises:
forming the first film, wherein the Ta—Si compound has a formula of TaSiₓ, wherein x is in a range of 1.0 to 3.0;
forming a second film over the first film, wherein the second film includes at least 90 wt % Al; and
forming a third film over the second film.

20. The process of claim 18, further comprising annealing the first and conductive layers at a temperature in a range of 620° C. to 890° C. for a time in a range of 60 s to 300 s, wherein the median contact resistance for the first and conductive layers is at most 0.30 ohm·mm.
